(19) United States
(12) Patent Application Publication
(10) Pub. No.: US 2020/0146189 A1
(43) Pub. Date: May 7, 2020

(54) SYSTEMS AND METHODS FOR COOLING WITH VARIABLE-LOCATION AIR MOVER

(71) Applicant: Dell Products L.P., Round Rock, TX (US)

(72) Inventors: Tung Yu CHIEN, New Taipei City (TW); Yen Ming WU, Taipei (TW); Hsiang-Ru CHENG, Taipei (TW); Kai Chieh CHIA, New Taipei City (TW)

(73) Assignee: Dell Products L.P., Round Rock, TX (US)

(21) Appl. No.: 16/181,728

(22) Filed: Nov. 6, 2018

(51) Int. Cl. H05K 7/20; G05B 15/02

(52) U.S. Cl. CPC H05K 7/20836; G05B 15/02; H05K 7/20736

(57) ABSTRACT

A system may include one or more heat-generating components, a chassis for enclosing the one or more heat-generating components, and a variable-location air mover subsystem comprising at least one air mover, a transmission system for varying a position of the at least one air mover relative to the chassis, and a control system. The control system may be configured to, in response to a condition for activating the at least one air mover, activate the at least one air mover and cause the at least one air mover to move from a first position relative to the chassis to a second position relative to the chassis.

### TECHNICAL FIELD

The present disclosure relates in general to information handling systems, and more particularly to controlling speed of an air mover during boot of an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

For traditional high-density server systems, air mover size selection may be critical. Often, smaller air movers with smaller air flow capacities are chosen, because in the event of a single air mover failure, a smaller amount of airflow will be lost due to the failure as compared to a larger air mover. However, an air mover system with smaller air movers for generating a desired air flow may be more costly than a similar system using larger air movers, as the system with smaller air movers requires a greater number of air movers, which may lead to higher design complexity, higher power consumption, and higher cost. Accordingly, improved solutions are desired.

### SUMMARY

In accordance with the teachings of the present disclosure, the disadvantages and problems associated with cooling in information handling systems may be substantially reduced or eliminated.

In accordance with embodiments of the present disclosure, a system may include one or more heat-generating components, a chassis for enclosing the one or more heat-generating components, and a variable-location air mover subsystem comprising at least one air mover, a transmission system for varying a position of the at least one air mover relative to the chassis, and a control system. The control system may be configured to, in response to a condition for activating the at least one air mover, activate the at least one air mover and cause the at least one air mover to move from a first position relative to the chassis to a second position relative to the chassis.

In accordance with these and other embodiments of the present disclosure, a method may include, in a variable-location air mover subsystem comprising at least one air mover and a transmission system for varying a position of the at least one air mover relative to a chassis for enclosing one or more heat-generating components, determining if a condition for activating the at least one air mover has occurred, and in response to occurrence of the condition for activating the at least one air mover, activating the at least one air mover and causing the at least one air mover to move from a first position relative to the chassis to a second position relative to the chassis. In accordance with these and other embodiments of the present disclosure, an article of manufacture may include a non-transitory computer readable medium and computer-executable instructions carried on the computer readable medium, the instructions readable by a processor, the instructions, when read and executed, for causing the processor to, in a variable-location air mover subsystem comprising at least one air mover and a transmission system for varying a position of the at least one air mover relative to a chassis for enclosing one or more heat-generating components: determine if a condition for activating the at least one air mover has occurred, and in response to occurrence of the condition for activating the at least one air mover activate the at least one air mover and cause the at least one air mover to move from a first position relative to the chassis to a second position relative to the chassis.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2A illustrates a perspective view of selected components of an example variable-location air mover subsystem having two axes of transmission, in accordance with embodiments of the present disclosure;

FIG. 2B illustrates a perspective view of selected components of an example variable-location air mover subsystem having one axis of transmission, in accordance with embodiments of the present disclosure;

FIG. 3A illustrates a perspective view of selected components of an example information handling system having a variable-location air mover subsystem with two axes of transmission, in accordance with embodiments of the present disclosure;

FIG. 3B illustrates a perspective view of selected components of an example information handling system having a variable-location air mover subsystem with one axis of transmission, in accordance with embodiments of the present disclosure;

FIG. 3C illustrates a perspective view of selected components of an example information handling system having an example variable-location air mover subsystem with one axis of transmission, in accordance with embodiments of the present disclosure; and

FIG. 4 illustrates a flow chart of an example method for operation of a variable-location air mover subsystem, in accordance with embodiments of the present disclosure.

### DETAILED DESCRIPTION

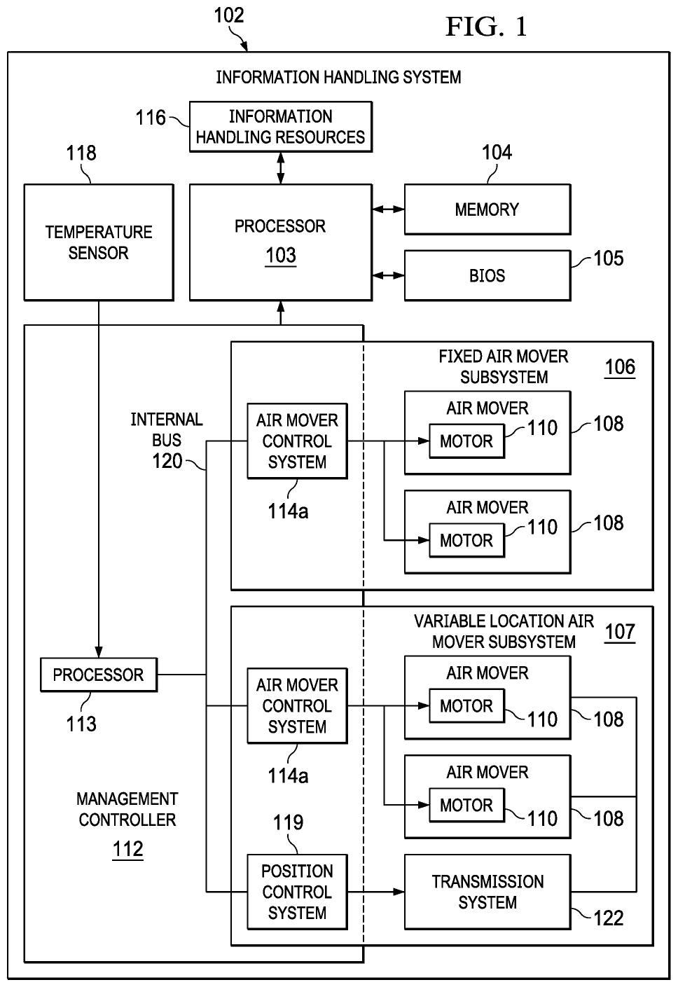

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104, a basic input/output system (BIOS) 105, a fixed air mover subsystem 106, a variable-location air mover subsystem 107, a management controller 112, information handling resources 116, and a temperature sensor 118.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

A BIOS 105 may include any system, device, or apparatus configured to identify, test, and/or initialize information handling resources of information handling system 102, and/or initialize interoperation of information handling system 102 with other information handling systems. “BIOS” may broadly refer to any system, device, or apparatus configured to perform such functionality, including without limitation, a Unified Extensible Firmware Interface (UEFI). In some embodiments, BIOS 105 may be implemented as a program of instructions that may be read by and executed on processor 103 to carry out the functionality of BIOS 105. In these and other embodiments, BIOS 105 may comprise boot firmware configured to be the first code executed by processor 103 when information handling system 102 is booted and/or powered on. As part of its initialization functionality, code for BIOS 105 may be configured to set components of information handling system 102 into a known state, so that one or more applications (e.g., an operating system or other application programs) stored on compatible media (e.g., disk drives) may be executed by processor 103 and given control of information handling system 102. In some embodiments, BIOS 105 may also be configured to store and/or report configuration information regarding a hardware configuration (e.g., population of various information handling resources) of information handling system 102.

Fixed air mover subsystem 106 may include an air mover control system 114a and one or more air movers 108. In fixed air mover subsystem 106, air movers 108 may be set in a fixed location relative to other components of information handling system 102. Functionality of air mover control system 114a may be disclosed in greater detail below with respect to the discussion of components of management controller 112.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, air mover 108 may comprise a blower (e.g., centrifugal fan that employs rotating impellers to accelerate air received at its intake and change the direction of the airflow). In these and other embodiments, rotating and other moving components of an air mover 108 may be driven by a motor 110. The rotational speed of a motor 110 may be controlled by an air mover control signal (e.g., a pulse-width modulation signal) communicated from air mover control system 114a of management controller 112. In operation, an air mover 108 may cool information handling resources of information handling system 102 by drawing cool air into an enclosure housing the information handling resources from outside the enclosure, expel warm air from inside the enclosure to the outside of such enclosure, and/or move air across one or more heat sinks (not explicitly shown) internal to the enclosure to cool one or more information handling resources.

Variable-location air mover subsystem 107 may include an air mover control system 114b, a position control system 119, a transmission system 122, and one or more air movers 108. Air movers 108 of variable-location air mover subsystem 107 may be similar in many respects to air movers 108 of fixed air mover subsystem 106. The rotational speed of a motor 110 of an air mover of variable-location air mover subsystem 107 may be controlled by an air mover control signal (e.g., a pulse-width modulation signal) communicated from air mover control system 114b of management controller 112. Unlike air movers 108 of fixed air mover subsystem 106, air movers 108 of variable-location air mover subsystem 107 may, as their name implies, variably move relative to other components of information handling system 102. Accordingly, position control system 119 and transmission system 122 may cause such movement of air movers 108 of variable-location air mover subsystem 107.

Transmission system 122 may comprise any suitable number of types of mechanical components (e.g., a servo motor or stepper motor, lead screw, driving board, etc.) mechanically coupled to air movers 108 of variable-location air mover system 107 and configured to cause air movers 108 of variable-location air mover system 107 to move in one or two axes relative to a chassis or other enclosure of information handling system 102, as described in greater detail below. The location(s) to which air movers 108 are translated by transmission system 122 may be controlled by position control system 119.

Functionality of air mover control system 114a and position control system 119 may be disclosed in greater detail below with respect to the discussion of components of management controller 112.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a processor 113, a plurality of air mover control systems 114 (e.g., air mover control systems 114a and 114b), a position control system 119, and an internal bus 120.

Processor 113 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 113 may interpret and/or execute program instructions and/or process data stored in memory 104 and/or another component of information handling system 102 or management controller 112.

An air mover control system 114 may include any system, device, or apparatus configured to, based on information communicated from processor 113 (e.g., information regarding a hardware configuration of information handling system 102) and/or thermal conditions present in information handling system 102 (e.g., one or more sensed temperatures from temperature sensor 118), calculate an air mover driving signal (e.g., a pulse-width modulation signal) to maintain an appropriate level of cooling, increase cooling, or decrease cooling, as appropriate, and communicate such air mover driving signal to air movers 108. In some embodiments, an air mover control system 114 may include a program of instructions (e.g., software, firmware) configured to, when executed by a processor or controller integral to management controller 112 (e.g., processor 113), carry out the functionality of an air mover control system 114.

Position control system 119 may include any system, device, or apparatus configured to, based on information communicated from processor 113 (e.g., information regarding a hardware configuration of information handling system 102) and/or thermal conditions present in information handling system 102 (e.g., one or more sensed temperatures from temperature sensor 118), calculate one or more driving signals to cause transmission system 122 to translate air movers 108 of variable-location air mover subsystem 107 relative to a chassis of information handling system 102, as described in greater detail below. In some embodiments, position control system 119 may include a program of instructions (e.g., software, firmware) configured to, when executed by a processor or controller integral to management controller 112 (e.g., processor 113), carry out the functionality of position control system 119.

Internal bus 120 may be a signal bus internal to management controller 112 communicatively coupling air mover control systems 114 to processor 113 and co-processor 115, to allow communication of control signals from either or both of processor 113 to air mover control systems 114, as described in greater detail herein.

Temperature sensor 118 may be any system, device, or apparatus (e.g., a thermometer, thermistor, etc.) configured to communicate a signal to processor 113 or another controller indicative of a temperature within information handling system 102. In many embodiments, information handling system 102 may comprise a plurality of temperature sensors 118, wherein each temperature sensor 118 detects a temperature of a particular component and/or location within information handling system 102.

In addition to processor 103, memory 104, BIOS 105, fixed air mover subsystem 106, variable-location air mover subsystem 107, management controller 112, and temperature sensor 118, information handling system 102 may include one or more other information handling resources. In addition, for the sake of clarity and exposition of the present disclosure, FIG. 1 depicts four air movers 108 and two air mover controller air mover control systems 114. In embodiments of the present disclosure, information handling system 102 may include any number of air movers 108 and/or air mover control systems 114.

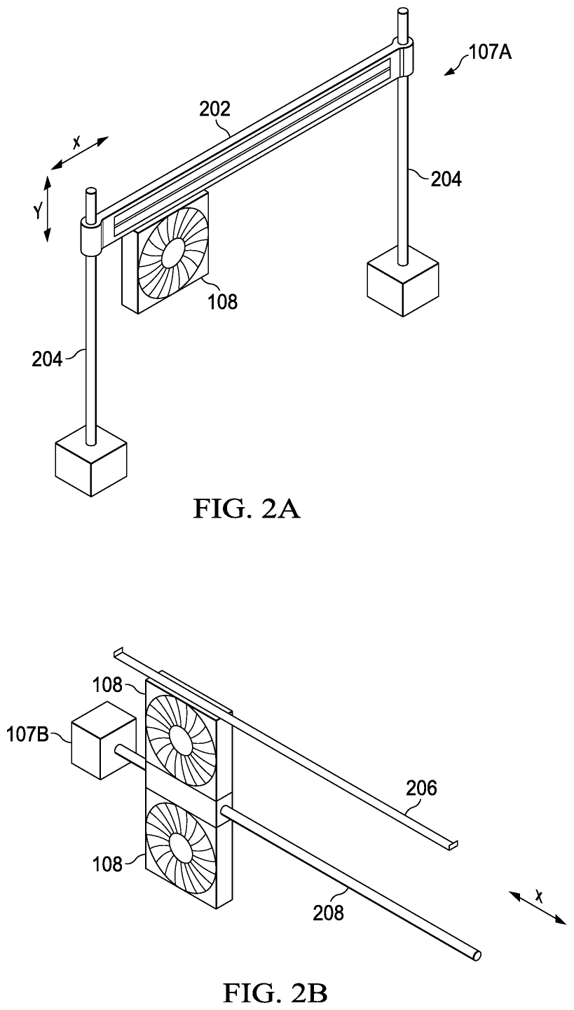

FIG. 2A illustrates a perspective view of selected components of an example variable-location air mover subsystem 107A having two axes of transmission, in accordance with embodiments of the present disclosure. In some embodiments, example variable-location air mover subsystem 107A may implement all or a part of variable-location air mover subsystem 107 shown in FIG. 1. As shown, an air mover 108 may be mechanically coupled to a track 202 which may in turn may be mechanically coupled to a track 204. In operation, a transmission system 122 (not shown in FIG. 2A) may drive the location of air mover 108 back and forth about track 202 in the direction X shown in FIG. 2A, while the same transmission system 122 or another transmission system 122 may drive the location of track 202 up and down about track 204 in the direction Y shown in FIG. 2B, allowing the position of air mover 108 to be varied in two dimensions.

FIG. 2B illustrates a perspective view of selected components of an example variable-location air mover subsystem 107B having one axis of transmission, in accordance with embodiments of the present disclosure. In some embodiments, example variable-location air mover subsystem 107B may implement all or a part of variable-location air mover subsystem 107 shown in FIG. 1. As shown, a plurality of air movers 108 may be mechanically coupled to tracks 206 and 208. In operation, a transmission system 122 (not shown in FIG. 2B) may drive the location of air movers 108 back and forth about tracks 206 and 208 in the direction X shown in FIG. 2B allowing the position of air movers 108 to be varied in one dimension. In some embodiments, variable-location air mover subsystem 107B may drive air movers 108 together so that air movers 108 have the same position along the axis of direction X. In other embodiments, variable-location air mover subsystem 107B may drive air movers 108 separately so that air movers 108 may have different positions in the axis of direction X.

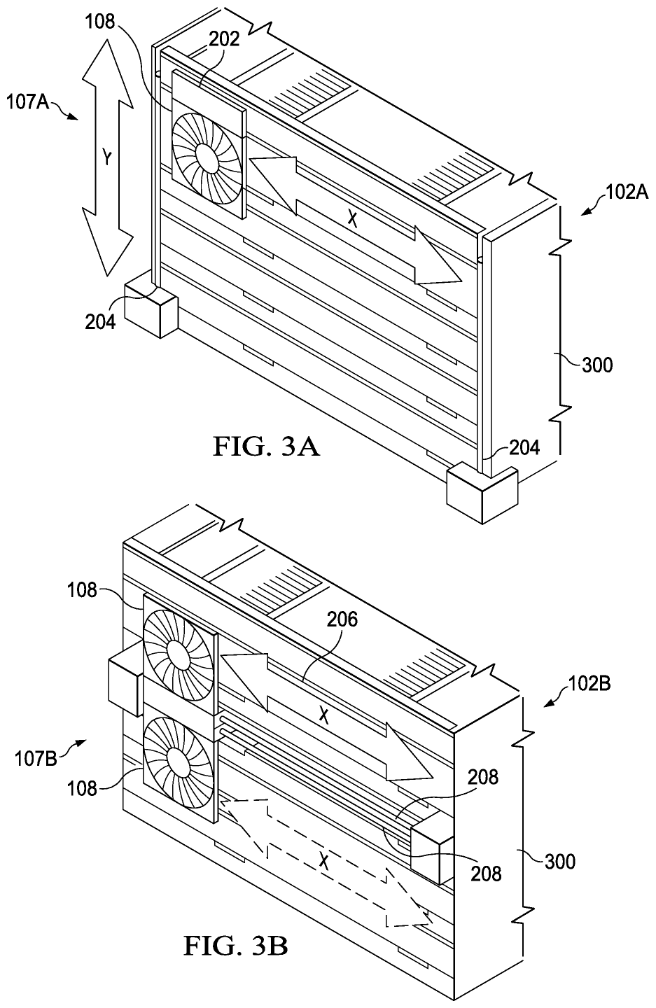

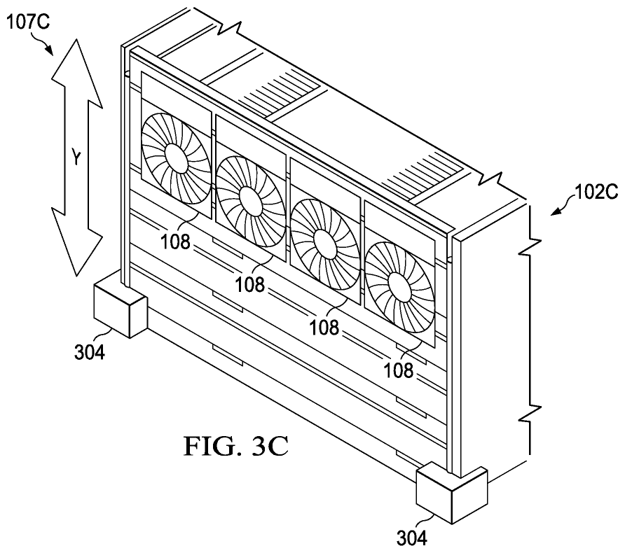

FIG. 3A illustrates a perspective view of selected components of an example information handling system 102A having variable-location air mover subsystem 107A with two axes of transmission, in accordance with embodiments of the present disclosure. As shown in FIG. 3A, air mover 108 may be variably positioned about two axes, directions X and Y, relative to chassis 300 of information handling system 102A, and be configured to drive airflow in a direction perpendicular to both directions X and Y. As such, transmission system 122 (not shown in FIG. 3A) and air mover 108 of variable-location air mover subsystem 107A may be positioned on one side of chassis 300, opposite of a side of chassis 300 in which fixed air mover subsystem 106 (not shown in FIG. 3A) is located.

FIG. 3B illustrates a perspective view of selected components of an example information handling system 102B having variable-location air mover subsystem 107B with one axis of transmission, in accordance with embodiments of the present disclosure. As shown in FIG. 3B, air movers 108 may be variably positioned about one axis, in direction X, relative to chassis 300 of information handling system 102B, and be configured to drive airflow into or out of chassis 300 in a direction perpendicular to direction X. As such, transmission system 122 (not shown in FIG. 3B) and air movers 108 of variable-location air mover subsystem 107B may be positioned on one side of chassis 300, opposite of a side of chassis 300 in which fixed air mover subsystem 106 (not shown in FIG. 3B) is located.

FIG. 3C illustrates a perspective view of selected components of an example information handling system 102C having an example variable-location air mover subsystem with one axis of transmission, in accordance with embodiments of the present disclosure. As shown in FIG. 3C, air movers 108 may be variably positioned about one axis, in direction Y, relative to chassis 300 of information handling system 102C, and be configured to drive airflow into or out of chassis 300 in a direction perpendicular to direction Y about tracks 304. As such, transmission system 122 (not shown in FIG. 3C) and air mover 108 of variable-location air movers subsystem 107C may be positioned on one side of chassis 300, opposite of a side of chassis 300 in which fixed air mover subsystem 106 (not shown in FIG. 3C) is located.

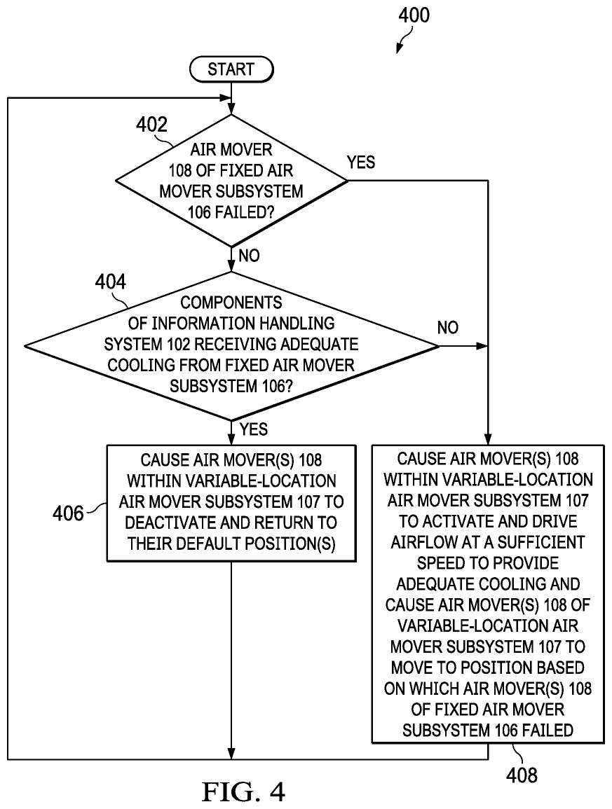

FIG. 4 illustrates a flow chart of an example method 400 for operation of a variable-location air mover subsystem 107, in accordance with embodiments of the present disclosure. According to one embodiment, method 400 may begin at step 402. As noted above, teachings of the present disclosure may be implemented in a variety of configurations of information handling system 102. As such, the preferred initialization point for method 400 and the order of the steps comprising method 400 may depend on the implementation chosen.

At step 402, processor 113 may determine if an air mover 108 of fixed air mover subsystem 106 has experienced a failure. If an air mover 108 of fixed air mover subsystem 106 has experienced a failure, method 400 may proceed to step 408. Otherwise, method 400 may proceed to step 404.

At step 404, processor 113 may determine if components of information handling system 102 are receiving adequate cooling from fixed air mover subsystem 106. For example, such determination may be made by determining a temperature sensed by temperature sensor 118, in that temperature sensor 118 sensing that the temperature is above a particular threshold may indicate that information handling system 102 is not being sufficiently cooled by fixed air mover subsystem 106. If components of information handling system 102 are receiving adequate cooling, method 400 may proceed to step 406. Otherwise, method 400 may proceed to step 408.

At step 406, responsive to nonexistence of air mover failures within fixed air mover subsystem 106 and adequate cooling provided by fixed air mover subsystem 106, processor 113 may cause (e.g., via air mover control system 114b) air mover(s) 108 within variable-location air mover subsystem 107 to deactivate (or, if already deactivated, to remain deactivated) and cause (e.g., via position control system 119) air mover(s) 108 of variable-location air mover subsystem 107 to return to their default position(s) (or, if already in their default positions, remain in such default position(s)). After step 406 completes, method 400 may return to step 402.

At step 408, responsive to existence of an air mover failure within fixed air mover subsystem 106 or inadequate cooling provided by fixed air mover subsystem 106, processor 113 may cause (e.g., via air mover control system 114b) air mover(s) 108 within variable-location air mover subsystem 107 to activate (or, if already activated, to remain activated) and drive airflow at a sufficient speed to provide adequate cooling and cause (e.g., via position control system 119) air mover(s) 108 of variable-location air mover subsystem 107 to move to a position based on which air mover(s) 108 of fixed air mover subsystem 106 failed (or, if already in such position, remain in such default position), to provide cooling in a region of information handling system 102 to which the failed air mover provided cooling. After step 408 completes, method 400 may return to step 402.

Although FIG. 4 discloses a particular number of steps to be taken with respect to method 400, method 400 may be executed with greater or lesser steps than those depicted in FIG. 4. In addition, although FIG. 4 discloses a certain order of steps to be taken with respect to method 400, the steps comprising method 400 may be completed in any suitable order.

Method 400 may be implemented using information handling system 102 or any other system operable to implement method 400. In certain embodiments, method 300 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
one or more heat-generating components;
a chassis for enclosing the one or more heat-generating components; and
a variable-location air mover subsystem comprising:
at least one air mover;
a transmission system for varying a position of the at least one air mover relative to the chassis; and
a control system configured to, in response to a condition for activating the at least one air mover:
activate the at least one air mover; and
cause the at least one air mover to move from a first position relative to the chassis to a second position relative to the chassis.

2. The system of claim 1, wherein the system comprises a fixed air mover subsystem having at least one second air mover with a fixed position relative to the chassis.

3. The system of claim 2, wherein the condition for activating the at least one air mover of the variable-location air mover subsystem comprises a failure of one or more of the at least one second air mover.

4. The system of claim 3, wherein the second position is based on a location of the one or more of the at least one second air mover which failed.

5. The system of claim 2, wherein the condition for activating the at least one air mover of the variable-location air mover subsystem comprises a temperature of the system exceeding a threshold temperature.

6. The system of claim 1, wherein the control system is configured to cause the at least one air mover of the variable-location air mover subsystem to move in one axis between the first position and the second position.

7. The system of claim 1, wherein the control system is configured to cause the at least one air mover of the variable-location air mover subsystem to move in two axes between the first position and the second position.

8. A method comprising, in a variable-location air mover subsystem comprising at least one air mover and a transmission system for varying a position of the at least one air mover relative to a chassis for enclosing one or more heat-generating components:
determining if a condition for activating the at least one air mover has occurred; and
in response to occurrence of the condition for activating the at least one air mover:
activating the at least one air mover; and
causing the at least one air mover to move from a first position relative to the chassis to a second position relative to the chassis.

9. The method of claim 8, wherein the condition for activating the at least one air mover of the variable-location air mover subsystem comprises a failure of one or more of at least one second air mover of a fixed air mover subsystem comprising the at least one second air mover wherein the at least one second air mover has a fixed position relative to the chassis.

10. The method of claim 9, wherein the second position is based on a location of the one or more of the at least one second air mover which failed.

11. The method of claim 8, wherein the condition for activating the at least one air mover of the variable-location air mover subsystem comprises a temperature exceeding a threshold temperature.

12. The method of claim 8, further comprising causing the at least one air mover of the variable-location air mover subsystem to move in one axis between the first position and the second position.

13. The method of claim 8, further comprising causing the at least one air mover of the variable-location air mover subsystem to move in two axes between the first position and the second position.

14. An article of manufacture comprising:
a non-transitory computer readable medium; and
computer-executable instructions carried on the computer readable medium, the instructions readable by a processor, the instructions, when read and executed, for causing the processor to, in a variable-location air mover subsystem comprising at least one air mover and a transmission system for varying a position of the at least one air mover relative to a chassis for enclosing one or more heat-generating components:
determine if a condition for activating the at least one air mover has occurred; and
in response to occurrence of the condition for activating the at least one air mover:
activate the at least one air mover; and
cause the at least one air mover to move from a first position relative to the chassis to a second position relative to the chassis.

15. The article of claim 14, wherein the condition for activating the at least one air mover of the variable-location air mover subsystem comprises a failure of one or more of at least one second air mover of a fixed air mover subsystem comprising the at least one second air mover wherein the at least one second air mover has a fixed position relative to the chassis.

16. The article of claim 15, wherein the second position is based on a location of the one or more of the at least one second air mover which failed.

17. The article of claim 14, wherein the condition for activating the at least one air mover of the variable-location air mover subsystem comprises a temperature exceeding a threshold temperature.

18. The article of claim 14, the instructions for further causing the at least one air mover of the variable-location air mover subsystem to move in one axis between the first position and the second position.

19. The article of claim 14, the instructions for further causing the at least one air mover of the variable-location air mover subsystem to move in two axes between the first position and the second position.
